(19) United States
(12) Patent Application Publication
(10) Pub. No.: US 2016/0189929 A1
(43) Pub. Date: Jun. 30, 2016

(54) RAPID TEM SAMPLE PREPARATION METHOD WITH BACKSIDE FIB MILLING

(71) Applicant: Omniprobe, Inc., Dallas, TX (US)

(72) Inventors: Matt Hammer, Plano, TX (US); Michael Dawson, McKinney, TX (US); Cheryl Hartfield, Plano, TX (US)

(21) Appl. No.: 14/926,648

(22) Filed: Oct. 29, 2015

Related U.S. Application Data
(60) Provisional application No. 62/069,922, filed on Oct. 29, 2014.
(60) Provisional application No. 62/082,682, filed on Nov. 21, 2014.

(51) Int. Cl. H01J 37/305; H01J 37/285

(52) U.S. Cl. CPC H01J 37/3056; H01J 37/285; H01J 2237/31749

(57) ABSTRACT

A method for TEM sample preparation with backside milling of a sample extracted from a workpiece in an energetic-beam instrument such as a FIB-SEM is disclosed. The method includes rotating a nanomanipulator probe tip holding an extracted sample by an angle calculated according to the geometry of the apparatus; moving the instrument stage to position a TEM grid in a fixed holder so that the plane of the TEM grid is substantially parallel to the required plane for the TEM sample; attaching the extracted sample to the TEM grid; and, tilting the stage by a stage-tilt angle, while maintaining the holder in the fixed orientation with respect to the stage, so that the axis of the ion beam is made substantially parallel to the required plane for the TEM sample; thereby placing the extracted sample into position for allowing backside milling to prepare a thinned cross-sectional sample for TEM viewing.

### CLAIM FOR PRIORITY

This application claims the priority of U.S. Provisional Patent Applications, Ser. No. 62/069,922, filed Oct. 29, 2014 and Ser. No. 62/082,682, filed Nov. 21, 2014, which applications are incorporated into the present application by reference in their entirety.

### BACKGROUND

1. Technical Field

The present disclosure describes methods for separating a sample from a workpiece, and particularly relates to a method for separating a small sample region from a workpiece in an energetic-beam instrument, such as a focused ion-beam instrument microscope (a FIB).

2. Background

There are many established approaches in electron microscopy for preparation of electron-transparent specimens from a workpiece for observation with the transmission electron microscope (TEM). TEM samples are typically <200 nm thick and <3 mm wide in any dimension. Frequently such samples are referred to as “TEM lamella”, or just “lamella”, especially if prepared by the FIB lift-out technique. In this disclosure, the terms “lamella” and “sample” are used interchangeably, unless the context requires otherwise. A typical dimension of a Ga⁺ FIB-prepared lamella is 5 μm (H)×10 μm (L)×0.1 μm (W). Although the height and length can vary, in some cases on the order of 100 μm for large samples, the width (i.e., the thickness of the lamella) will always be on the order of roughly <500 nm, depending on the material type and goal of analysis.

Although the lamella is a three-dimensional object, because it is so thin (down to <20 nm thick for some samples), it can be thought of as a two-dimensional object in the form of a sheet. This sheet then defines the “lamella plane”. In a heterogeneous workpiece there are two types of lamella planes: cross-sectional and planar. A cross-sectional plane is perpendicular to the workpiece top surface. A planar plane is parallel to the workpiece top surface. Lamellae created with planar lamella planes are very useful to view larger areas than are visible in a cross-sectional plane, if searching for a defect or anomaly within a specific depth of the sample. These are often called plan-view samples. Cross-sectional planes are useful for metrology and understanding defects passing through multiple layers or a large depth. In practice, the vast majority of lamella prepared is the cross-sectional plane type. Unless specifically stated otherwise in the literature, generic references to FIB lift-out samples and lamella in this disclosure are always assumed to be of the cross-sectional type.

TEM samples are typically placed upon objects known as “grids” for introduction into the TEM. Grids are 3 mm disks with electron-transparent areas. They typically comprise a conductive metal and are <100 μm thick. To accommodate the need to mill TEM lamella with a FIB, custom grids known as “lift-out grids” were created. These differ from the traditional grids in that they are approximately half the normal grid dimension. In other words, instead of a 3 mm diameter circular disk, a lift-out grid is 3 mm wide in its long dimension and about 1.5 mm tall, maintaining the common thickness of <100 μm. These grids, like lamella, can be thought of as two-dimensional like a sheet, as they are extremely thin in one dimension. This sheet then defines the “grid plane”. The desired TEM viewing angle will be roughly perpendicular to the grid plane. For this reason, the lamella must be placed on the lift-out grid so the lamella plane is parallel to the grid plane.

As shown in FIG. 5, the lift-out grid 210 has a top edge 220 and a bottom edge 230. The bottom edge 230 is held by the grid holder 250. Structures commonly referred to by users as “fingers” or “posts” 240 project from the top edge 220 and are also in the grid plane. These serve as the sites for placing lift-out samples 170, and the lift-out grid 210 is always positioned for final lamella thinning so that the grid posts 240 are, within a few degrees of tolerance, parallel with the axis of the FIB ion beam 110 and pointing towards the ion beam 110. It is common to place a grid 210 in a FIB so the grid plane 260 is normal to the stage 160 with the bottom edge 230 of the grid 210 closest to the stage 160, and to move the stage 160 so that the FIB-SEM stage tilt axis 165 is coplanar with the grid plane 260.

It is most common to perform the lift-out technique in a FIB instrument which also includes a scanning electron microscope (SEM) capability. Such instruments are known as FIB-SEM, and in these instruments, the ion beam hits the sample at an angle of incidence (AOI) θᵢ, which is the angle measured from the ion beam to the workpiece surface normal. In the common arrangement of FIB-SEMS with a vertical imaging column parallel to stage normal and an ion column mounted obliquely to stage normal, this angle will always be some value between 0° and 90° at 0° stage tilts. Most FIB-SEMs have θᵢ in the range of 50°-60° at 0° stage tilt. Angle θᵢ changes as the sample surface is tilted with the FIB-SEM stage. To calculate the new AOI, one subtracts the stage tilt angle from θᵢ. If the stage is tilted towards the ion column, θᵢ grows smaller. If the stage is tilted away from the ion column, θᵢ grows larger. Most FIB-SEM stages have a maximum tilt towards the ion column of less than 90°. It is most common to tilt the stage normal towards the ion beam for processing or imaging with ions so this is often referred to as a “positive tilt”. If the stage normal is tilted away from the ion beam (“negative tilt”), eventually the stage will collide with the ion beam pole piece. One method of providing a wider range of angles is to add a special holder to the stage that can be controlled and tilted relative to the stage.

Since the semiconductor industry first adopted the FIB-SEM approach to making TEM lamellae, a range of FIB techniques have been developed to make TEM sample preparation more efficient. One successful approach relies on the use of FIB-mounted manipulators (also called “nanomanipulators”) to assist with in-situ transfer of lamellae from the workpiece to TEM grids. As used in this disclosure, the term “nanomanipulator” refers to any device for holding and manipulating a sample or lamella, and may include nanomanipulators with end effectors such as probe tips (often simply called probes or probe needles) or grippers or other such devices known in the art.

This in situ transfer process became known as in-situ lift-out (INLO). The steps of this method begin in a vacuum chamber with a focused ion beam impinging the front surface (frontside) of a workpiece to excavate material. The ion beam is patterned to mill material around a region of interest (ROI) that contains the required lamella plane. The ROI is eventually undercut by the ion beam, and when all remaining connections to the workpiece are severed by the FIB, the sample is lifted out by the nanomanipulator and transferred for analysis and final shaping, using the FIB to remove extraneous material, thus creating the thin lamella or any other desired structure.

One of the first decisions when starting any in situ lift-out process is to determine the stage tilt required for both attaching a sample to a probe tip, and attaching the same sample to a grid. For a common frontside cross-sectional sample prepared by the FIB in situ lift-out method, it is common to attach the sample to the grid using the same stage tilt as used during the lift-out. Most frequently, a 0° stage tilt is used for lift-out. An example where tilting the stage more than 0° is used in order to perform the lift-out is in those cases where, due to sample topography, tilting enables better gas flux for the probe tip attachment step, or gives better access of the probe tip to the sample. Using probe rotation is a convenient way to add another degree of freedom to the in situ sample manipulation for more advanced sample preparation such as the need to make plan-view samples or to thin samples in an inverted position. Probe rotation will move the TEM sample plane to a new angle. The grid will then have to be moved to the same new angle in order to join the sample to the grid with the grid and TEM sample planes parallel. In some configurations, the effects of probe tip rotation are easy to anticipate. For example, if the probe tip is fixed to the sample with the tip axis at 45° to the sample surface, then a 180° rotation of the tip about its axis will tilt the sample surface by 90°.

For cases that are not as obvious as the example above, the geometry of the FIB-SEM configuration can be used to calculate steps to manipulate a sample to a desired orientation by exploiting conversion of angle-axis representation to rotation-matrix representation, as described by Craig, John J., “Introduction to Robotics Mechanics & Control,” Addison-Wesley Publishing Co., 1986, p322. The stage frame of reference is used for the geometrical factors of the FIB, which include the nanomanipulator's location on the FIB-SEM, the stage position (tilt and rotation), and probe rotation. The desired final orientation of the sample relative to objects in the stage frame of reference is specified in order to start the calculations. By knowing the probe tip elevation angle and the angle formed in the XY plane between the projection of the probe tip's axis and the projection of the stage tilt axis, along with the stage tilt required for lift-out, one can calculate the combined movements of a required stage rotation to move a sample before lift-out and the probe rotation required after lift-out for achieving a desired sample orientation of the sample on the probe tip. The sample is then ready for attaching to a grid that can be further manipulated as required for the final sample geometry. An example of such a method is disclosed in U.S. Pat. No. 8,168,949, titled “Method for STEM sample inspection in a charged particle beam instrument”, which patent is incorporated by reference into the present application in its entirety, but which is not admitted to be prior art by its inclusion in this Background section.

FIB-SEM sample-preparation advances have been required for avoidance of curtaining artifacts, which result from differential milling rates of various materials in a sample. Curtaining artifacts not only degrade TEM image quality, but also limit the final thickness of the TEM sample; therefore curtaining artifacts have become an increasing limitation as TEM samples of reduced thickness are required with a typical lamella thickness requirement of less than 20 nm for some sample types.

One way to address the curtaining artifact is to advantageously adjust the position of the cross-sectional lamella before proceeding with final shaping. Cross-sectional lamella have six surfaces: a top surface or “front side” corresponding to the top surface of the workpiece, a back side that is opposite the top surface and corresponds to the bottom of the workpiece (also called “the backside”), a first cross-sectional face and a second cross-sectional face, corresponding to the two sides parallel to the lamella plane, and two surfaces orthogonal to the lamella plane. In order to create a lamella of a desired thickness, the FIB thinning is performed with the ion beam axis roughly parallel to the required lamella plane. If lamella thinning occurs with the ion beam impinging the lamella front surface, this is known as frontside sample preparation, which produces a frontside sample. If a lamella is thinned with the ion beam impinging the back side, this is known as backside sample preparation, which produces a backside sample. Typically cross-sectional plane lamellae are made using frontside preparation, because the process is very simple with no changes required to the sample orientation in order to produce the thin lamella. However, curtaining effects may be a problem with frontside preparation.

Backside sample preparation, although more lengthy and difficult because it involves steps to turn the lamella upside down from its original orientation, does reduce curtaining effects. Backside preparation is highly desirable because in some sample types, it is the only approach that can yield a high quality TEM lamella of even thickness and minimal curtaining artifact. Backside FIB milling is typically performed after the lamella has been extracted from the workpiece and placed onto a lift-out grid in the FIB.

In general, state-of-the-art FIB backside preparation takes several approaches in order to invert a lamella by 180° from its original position as lifted from the workpiece. In some methods, there is more than one lifting step required, as the lamella orientation is changed only by a combination of multiple lifting steps and grid attachment steps with the grid position changed each time until a 180° orientation producing a backside sample is obtained. The grid angle may be changed in-situ using motorized grid holders that tilt or rotate, or ex-situ on the bench using direct manual handling of the grid with tweezers, or by the direct handling of a non-motorized pivoting grid holder. In some cases, rather than placing the lamella on a grid, it may be placed at some point in the workflow on a temporary holder such as a second probe tip or even the bulk workpiece from whence the lamella was taken. Once the lamella is mounted onto the grid in its final desired backside orientation, it is thinned using a positive stage tilt to orient the ion beam axis substantially parallel to the lamella plane, as is known in the art. While these methods do achieve a backside sample, they can be tedious to perform, requiring multiple lift-out steps as well as the use of special temporary holders or tiltable grid holders and in some cases also require venting of the FIB-SEM for ex-situ manipulation.

To improve efficiency, methods have arisen to create backside samples using only a single lift-out step, by taking advantage of a combination of rotating the probe tip between the lift-out and attach steps, to change sample orientation, and using a grid mounted to the FIB stage on a tiltable grid holder. The mechanism to tilt the grid holder has to be motorized so that the procedure can be completed under vacuum without removing the holder from the chamber. As in the previous methods, once the lamella is on the grid in its final desired backside orientation with grid and lamella planes parallel to each other, it is thinned using a positive stage tilt to decrease the ion beam angle of incidence, thus aligning the lamella plane substantially parallel to the ion beam axis. Although these known methods achieve a backside sample using a single lift-out step, they do have the requirement of a custom motorized tiltable grid holder, along with an extra step to tilt the grid holder, before making the positive stage tilt to position the lamella for backside thinning.

All above methods and approaches fail to provide the most efficient and cost-effective means to obtain a cross-sectional TEM lamella positioned for backside milling with the ion beam axis substantially parallel to the lamella plane. Cost effectiveness and efficiency require both a single lift-out step and the execution of all steps in the vacuum chamber, using only a nanomanipulator, a fixed-position grid holder, and the native stage XYZ translation, rotation and tilt capability of the FIB microscope.

### DRAWINGS

Non-limiting embodiments of the present disclosure are described by way of example in the accompanying drawings, which are schematic and are not intended to be drawn to scale.

FIG. 1 is a perspective view showing the major parts of a typical energetic-beam, or FIB-SEM, instrument.

FIGS. 2A and 2B are views of a sample excision site on a workpiece, from the view of the electron beam and the ion beam, respectively.

FIGS. 3A and 3B are views of attaching the probe tip and lifting the sample, from the view of the electron beam, respectively. FIG. 3C shows the ion beam view for attaching the probe tip and 3D is ion beam view after lifting.

FIGS. 4A and 4B are views of sample rotation after lift-out, from the view of the electron beam and the ion beam, respectively.

FIGS. 5A and 5B are views of a typical grid aligned for attachment of the sample to the grid, from the view of the electron beam and the ion beam, respectively.

FIGS. 6A and 6B are close-up views of a sample attached to a grid in the required orientation with the backside pointing away from the grid and the lamella plane parallel to the grid plane, from the view of the electron beam and the ion beam, respectively.

FIGS. 7A and 7B are views of a sample attached to a grid, where the grid and attached sample are now aligned by a rotation (7A) and a tilt (7B) for a backside thinning operation with the grid plane parallel to the stage tilt axis and the sample backside facing the ion beam, from the view of the electron beam.

FIGS. 8A and 8B are views of a sample attached to a grid, where the grid and attached sample are now aligned by a rotation (8A) and a tilt (8B) for a backside thinning operation with the grid plane parallel to the stage tilt axis and the sample backside facing the ion beam, from the view of the ion beam.

FIG. 9 is a flowchart illustrating the steps in an embodiment of the method.

FIG. 10 is an example of a fixed-position grid holder.

### SUMMARY

We disclose a method for high quality TEM sample preparation using the FIB in situ lift-out technique to achieve backside sample thinning with one lift-out step and no sample or grid removal from the chamber, using only the FIB stage 5 degrees of motion for positioning the sample and grid, a manipulator with a shaft holding an end effector such as a probe tip or gripper, which can be rotated about the shaft axis and has a shaft axis that is collinear with end effector axis and intersects the FIB stage at an oblique angle, and a lift-out grid held in a fixed holder mounted to the stage at a fixed angle.

A lift-out sample is created by FIB milling a work piece around an area of interest that contains a sample plane that will be viewed in the TEM. The sample has a top surface which was originally part of the workpiece surface and a backside that is opposite to the top surface. A probe tip is attached to the lift-out sample by beam induced deposition either before or after the sample is completely separated from the workpiece as is known in the art, and the sample is then lifted free. remaining attached to the probe tip. The probe tip is rotated about its axis a calculated amount based on the geometry of the probe tip axis relative to the top surface of the sample and the FIB stage tilt axis, and the fixed angle between the grid plane and stage. The FIB stage is moved using its available degrees of freedom until the grid plane and required sample plane are parallel, with the backside of the sample facing away from the main body of the grid. The sample is attached to the grid by beam-induced deposition, the probe is detached from the sample by milling with the ion beam, and then using only stage rotation and stage tilt, the grid is oriented so the sample backside is facing the ion beam with the ion beam axis substantially parallel to the required sample plane. Backside thinning is then carried out to prepare a thinned cross-sectional lamella for TEM viewing.

### DETAILED DESCRIPTION

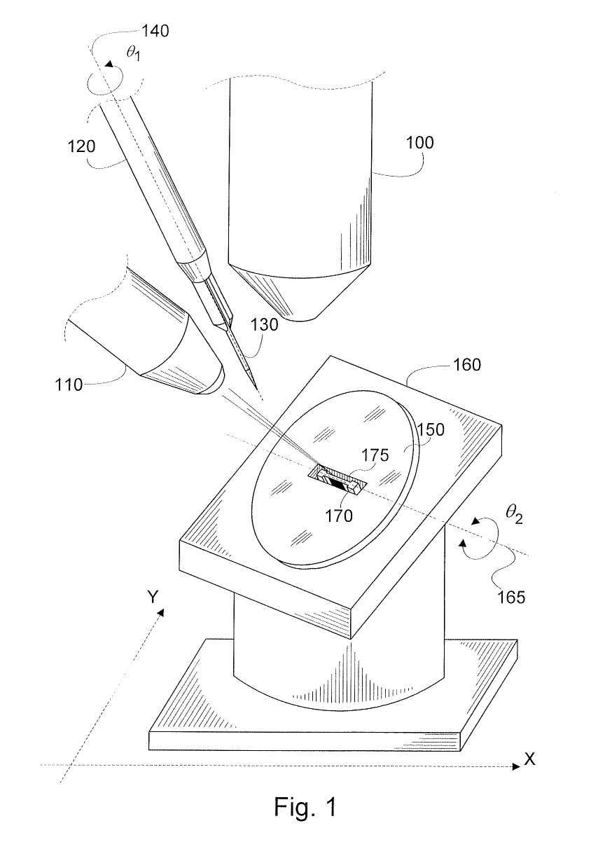

FIG. 1 is a schematic drawing of a FIB instrument having an electron beam column 100, an ion beam column 110 and a nanomanipulator 120 holding a probe tip 130; the probe tip 130 having a rotation axis 140. A workpiece 150 is shown located on the FIB stage 160, tilted, as shown here, to a positive tilt angle about its tilt axis 165 which is orthogonal to the ion beam 110. FIG. 1 further shows a sample 170 that has been excised from the workpiece 160, for example by milling with the ion beam 110. The relative sizes of the sample 170, and the trench 175 from which it was cut have been greatly exaggerated for clarity. A typical specimen to be prepared, for example, for TEM examination would be about 10 to 20 μm across.

In this disclosure, unless otherwise stated, the terms “electron beam” and “ion beam” refer to the beams of energetic particles, and also the axes of such beams, emitted by the electron-beam column 100 and ion-beam column 110, respectively, as shown in FIG. 1, and the same reference numerals apply. (In some instruments the electron beam may be substituted with another imaging beam, such as He ions, and this is an equivalent.)

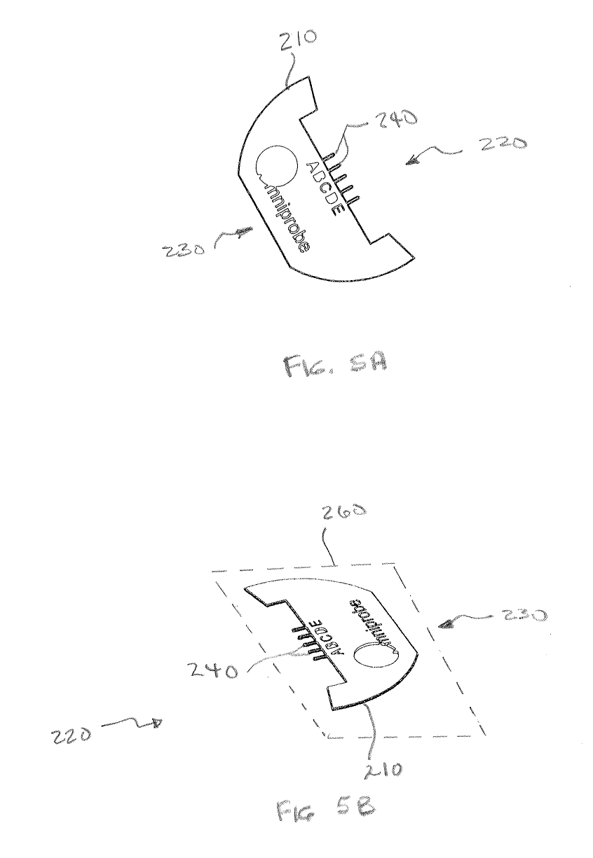

The method here disclosed employs, first, any of the methods described in the Background including a rotation of the probe tip 130 to create the TEM sample 170 and transfer it to a TEM grid 210 (see FIG. 5) in a desired orientation using common lift-out practices. Then, after the TEM sample 170 is transferred from the probe tip 130 of the nanomanipulator 120 to the grid 210, it is further oriented using only the available degrees of freedom of the FIB stage 160_ including rotation and a tilt of the stage 160 and rotation of the probe tip 130 so that the required sample plane 180 becomes substantially parallel to the ion beam 110 for backside ion milling.

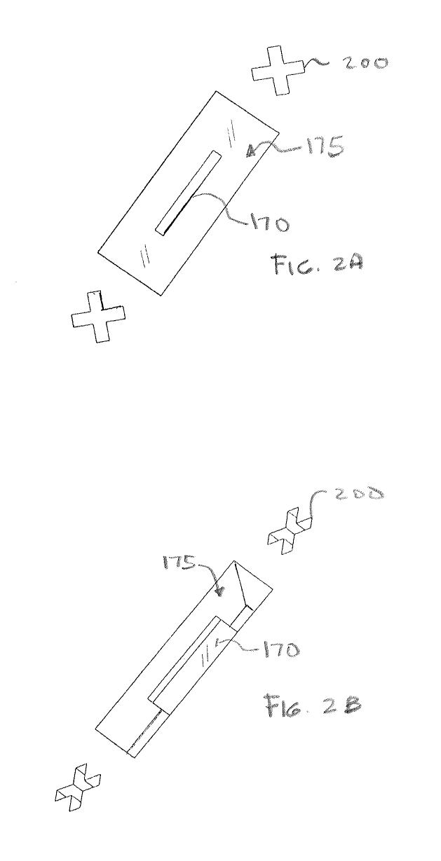

FIGS. 2A and 2B show views of a sample 170 excised from a workpiece 150, from the view of the FIB's electron beam 100 and ion beam 110, respectively. The figures show typically-used fiducial marks 200 in the workpiece 150, but such marks are not required.

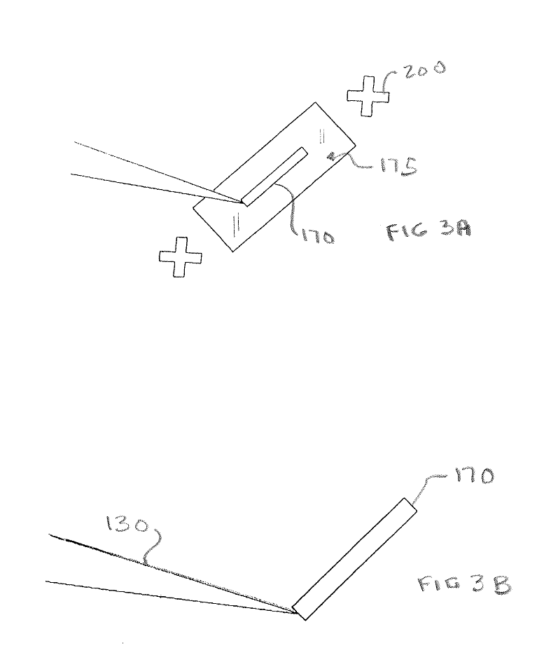

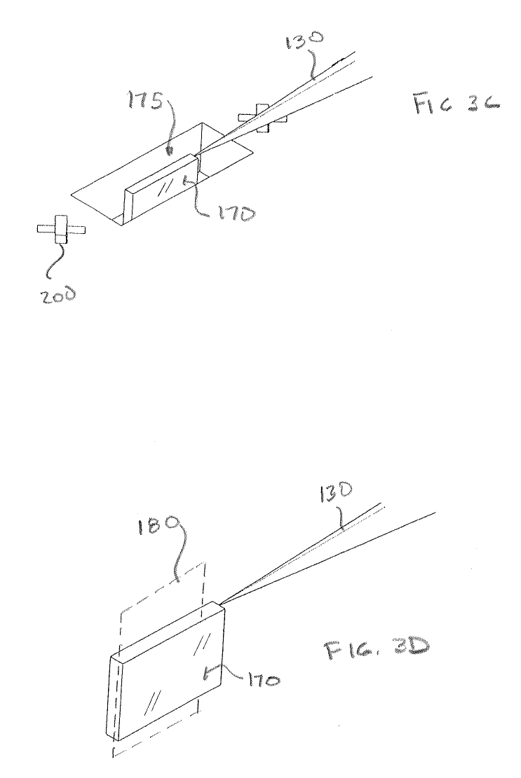

FIG. 3A shows the sample 170 attached to a probe tip 130 and FIG. 3B shows the sample 170 lifted out from the workpiece 150, from the view of the electron beam 100. FIGS. 3C and 3D shows the same operations from the view of the ion beam 110. Such lift-out methods are known in the art.

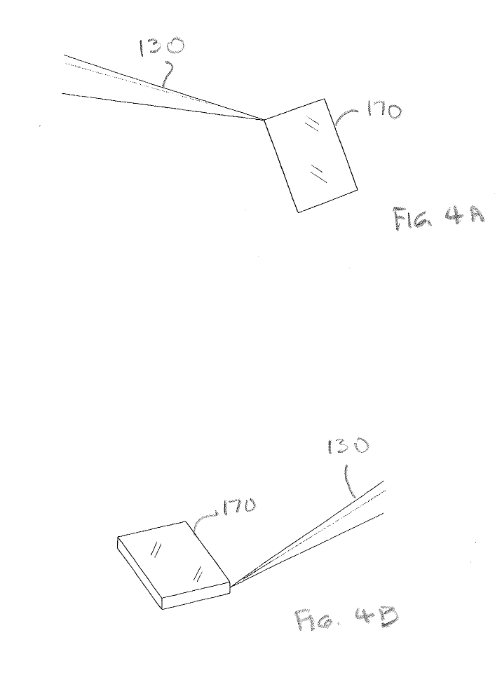

FIGS. 4A and 4B shows views of the sample 170 after the probe tip 130 has been rotated by the prescribed amount from the view of the FIB's electron beam 100 and ion beam 110, respectively.

FIGS. 5A and 5B shows views of the grid 210, initially loaded with its plane 260 orthogonal to the electron beam 100 after it has been rotated by the prescribed amount from the view of the FIB's electron beam 100 and ion beam 110, respectively.

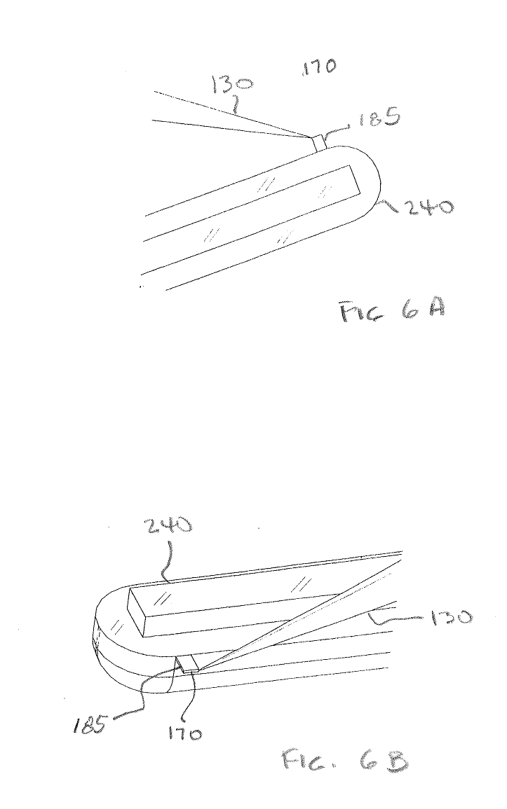

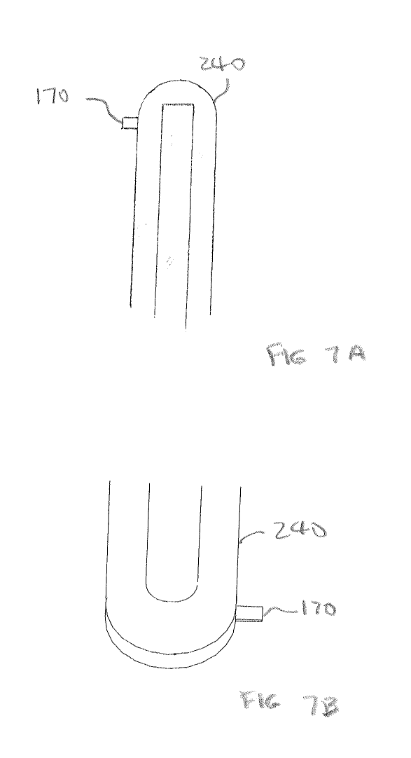

FIGS. 6A and 6B show views of the sample 170 being placed on the grid 210 in the required orientation for grid attachment for backside thinning from the view of the FIB's electron beam 100 and ion beam 110, respectively. The sample backside 185 is pointing towards the top edge 220 of the grid 210, and the grid 210 and sample lamella plane 180 are parallel.

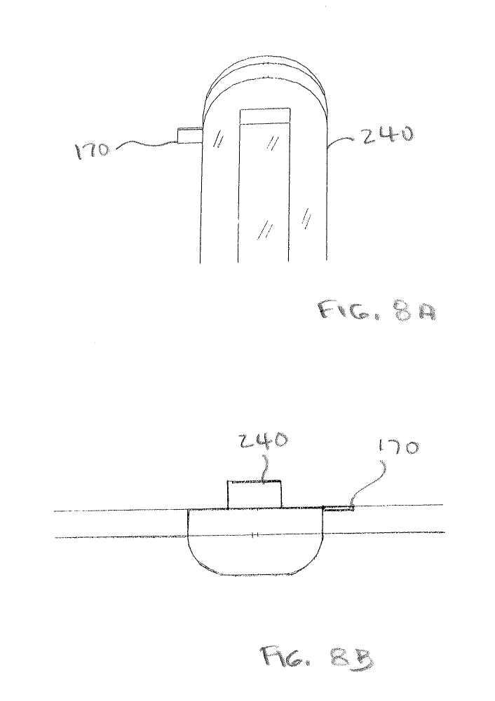

FIGS. 7A and 7B show the final steps to align the grid 210 to the ion beam 110 for backside thinning of the sample 170 using only the FIB stage 160, from the view of the FIB's electron beam 100. 7A shows the view after the stage 160 is rotated the calculated amount and 7B shows the view with the stage 160 tilted to bring the sample's lamella plane parallel to the ion beam for thinning.

FIGS. 8A and 8B show the final steps to align the grid 210_to the ion beam 110 for backside thinning of the sample 170 using only the FIB stage 160, from the view of the FIB's ion beam 110. FIG. 8A shows the view after the stage 160 is rotated the calculated amount and FIG. 8B shows the view with the stage 160 tilted to bring the sample's lamella plane parallel to the ion beam for thinning.

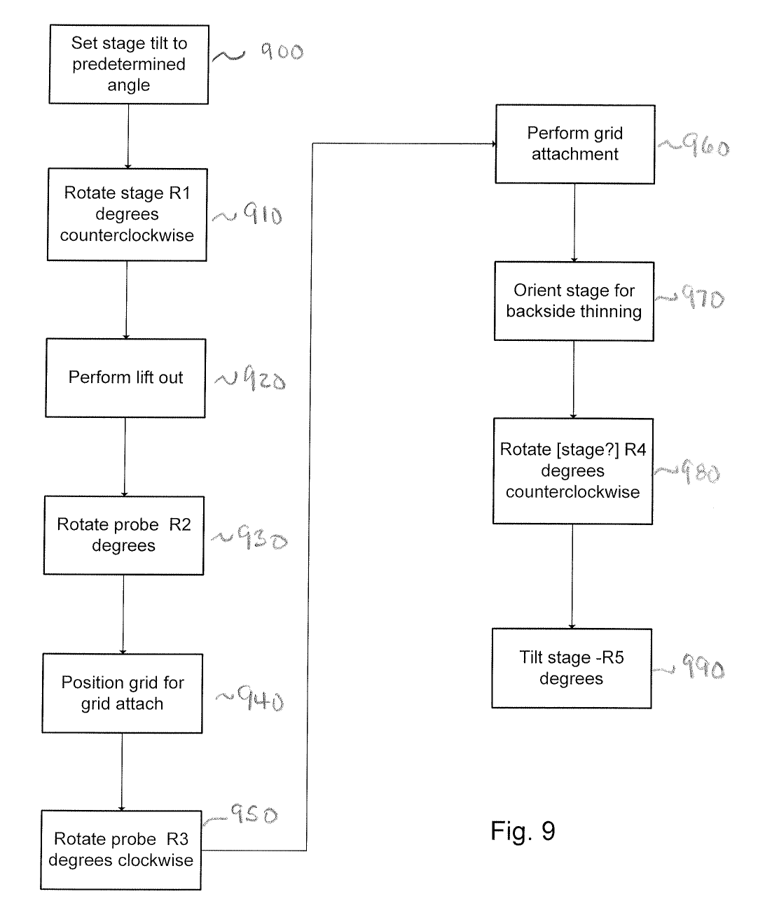

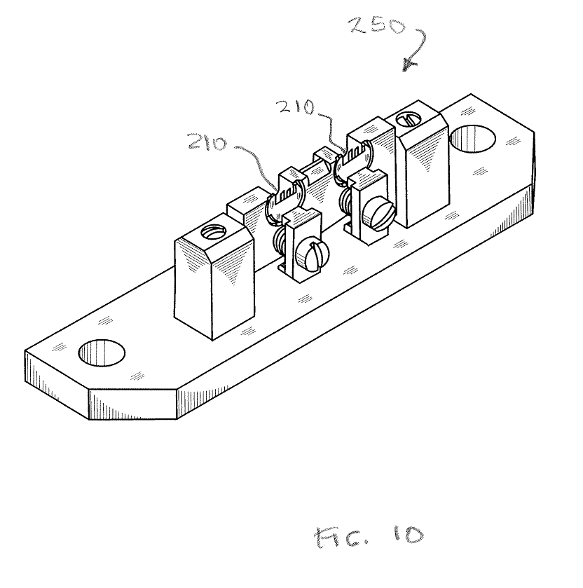

FIG. 9 shows a flow chart of steps according to one embodiment of the method.

To perform the FIB in situ lift-out method, a grid 210 must be pre-loaded into a holder 250, illustrated in FIG. 10, designed to hold the grid 210 at a fixed angle relative to the stage 160. This is normally done on a bench top using tweezers. The TEM grid 210 is considered to have a plane 180. The common grid position for regular cross-sectional samples is for the grid 210 to be loaded on a holder 250 that is then mounted on the stage 160 so the grid plane 260 intersects the stage surface at 90° and the top edge 220 of the grid 210 points away from the holder 250. For backside preparation as described here, it is advantageous to load the grid 210 on a holder 250 at a fixed angle so that when placed on the stage 160, the grid plane 260 intersects the stage surface at a value less than 90°. It is convenient to use an angle of 0° in this method for backside preparation, although other angles could be used also. The fixed angle of the holder 250 may be built into the holder 250, or it may be adjustable as long as it meets the requirement that the position is set to a fixed angle and the fixed angle is permanently maintained throughout the entire process.

Considering steps after the TEM sample 170 has been at least partially released from the workpiece 150, the following steps are performed. The steps depicted in the following illustrations are also represented in the flowchart of FIG. 9.

Rotate the stage 160 to move the sample 170 with an angle R₁ in preparation for lift-out. A common starting workpiece position for the rotation is with the required sample plane 180 parallel to the FIB stage tilt axis 165 and parallel to stage normal. Attach the probe tip 130. Lift-out the TEM sample 170 . By rotating the probe tip 130 about its axis, rotate the TEM sample 170 with an angle R₂ in preparation for attachment to the grid 210. This is the intermediate orientation with the required TEM sample plane 180 angled from the horizontal by the same angle that the grid plane 260 makes with the stage 160. In the embodiment shown here, where the grid plane 260 makes an angle of zero with the stage surface, the intermediate orientation places the sample cross-sectional lamella plane 180 orthogonal to the electron beam 100. The sample is considered to have a cross-sectional plane 180, shown schematically in FIGS. 3B and 4A and 4B.

Align the grid 210 by rotating the stage 160 with an angle R₃, which positions the backside 185 of the TEM sample 170 pointing away from the grid 210 with the cross-sectional plane 180 parallel to the plane of the grid 210.

Attach the TEM sample 170 to the grid 210. Cut the probe tip 130 free using the ion beam 110.

Position the TEM sample 170 for backside milling by rotating the stage 160 through an angle R₄ and tilting the stage 160 with an angle R₅ to place the TEM sample 170 parallel to the ion beam 110 and exposed for backside milling.

Particular angles appropriate for the steps above depend on the particular angle between the electron beam 100 and the ion beam 110 of the FIB-SEM and orientation of the nanomanipulator 120, all with respect to the stage normal and stage tilt axis 165.

An exemplary flow chart of the method disclosed here is set out in FIG. 9 of the attached drawings. As stated therein, the reader should note that the particular angles represented in FIG. 9 will depend on the particular angle between the ion beam 110 and the electron beam 100, and the orientation of the nanomanipulator 120. In FIG. 9, the exemplary procedure starts with the stage 160 at predetermined angle of tilt. At step 910, the stage 160 is rotated R1 degrees counter clockwise. At step 920, liftout is performed. At step 930, the probe tip 130 is rotated R2 degrees. At step 940 the grid 210 is positioned for the grid-attachment step. At step 950 the probe tip 130 is rotated R3 degrees clockwise. At step 960 the grid attachment is performed. At step 970 the stage 160 is oriented for thinning. At step 980 the stage 160 is rotated R4 degrees counter clockwise. At step 990, the stage 160 is tilted −R5 degrees, so that backside thinning may begin.

In one embodiment the ion beam axis makes an angle of 55 degrees and the nanomanipulator rotation axis makes an angle of 50 degrees with the electron beam axis. In a projection in the direction of the electron beam, if the ion beam axis direction is at zero degrees, the projected nanomanipulator rotation axis is at 80 degrees in the XY plane of the stage. From a position where the stage is normal to the electron beam direction, positive stage tilt brings the stage normal closer to the ion beam direction. For this embodiment, the following angles are suitable:
R₁=47.0° counter clockwise
R₂=134.8° clockwise
R₃=67.0° clockwise
R₄=67.0° counter clockwise
R₅=−35.0°

In another embodiment, with lift-out performed at 0° stage tilt and the grid held in the fixed holder so the grid plane is inclined 10° to the stage surface the following angles are suitable:
R₁=80.0° counter clockwise
R₂=180°
R₃=100.0° clockwise
R₄=−100.0° counter clockwise
R₅=−25.0°

Finally, in some cases there may be more than one recipe that can provide a back side orientation for a given hardware configuration and therefore it may be possible to optimize the angles for probe tip 130 attach, or the grid 210 attachment, or either. For example, one may design a recipe where attachment steps are performed at high tilt stage 160 angles to maximize the gas flux during the attachment process. Alternately, one may design a recipe where attachment steps are performed at zero-degrees stage 160 tilt to improve throughput by reducing the number of steps that require operation of the microscope stage 160.

None of the description in this application should be read as implying that any particular element, step, or function is an essential element which must be included in the claim scope; the scope of patented subject matter is defined only by the allowed claims. Moreover, none of these claims are intended to invoke paragraph six of 35 U.S.C. Section 112 unless the exact words “means for” are used, followed by a gerund. The claims as filed are intended to be as comprehensive as possible, and no subject matter is intentionally relinquished, dedicated, or abandoned.

We claim:

1. A method for TEM sample preparation with backside milling of a sample extracted from a workpiece in an energetic-beam instrument, where the energetic-beam instrument comprises: a focused ion beam, a stage capable of motion and tilting, a TEM grid held in a fixed holder on the stage, the TEM grid having a plane and the holder mounted in a fixed orientation with respect to the stage, and a probe tip rotatably connected to a nanomanipulator; the sample having a top surface and a backside and a required plane for the TEM sample that is normal to the top surface of the sample, and the sample being attached to the probe tip; the method comprising:
rotating the probe tip by an angle calculated according to the geometry of the apparatus;
moving the stage to position the TEM grid so that the plane of the TEM grid is substantially parallel to the required plane for the TEM sample;
attaching the extracted sample to the TEM grid and removing the attachment of the probe tip to the extracted sample; and,
tilting the stage by a stage-tilt angle, while maintaining the holder in the fixed orientation with respect to the stage, so that the axis of the ion beam is made substantially parallel to the required plane for the TEM sample;
thereby placing the extracted sample into position for allowing backside milling by the focused ion beam to prepare a thinned cross-sectional sample for TEM viewing.

2. The method of claim 1, where the workpiece is a semiconductor wafer.

3. The method of claim 1, where the angle of rotation of the probe tip is a function of the angle of the axis of the probe tip with respect to the top surface of the extracted sample, the tilt angle of the stage, and angle between the plane of the TEM grid and the stage.

4. The method of claim 1 where the sample is attached to the TEM grid so that the required plane for the TEM sample is parallel to the plane of the TEM grid, and the so that the ion beam impinges upon the backside of the sample when the axis of the ion beam is substantially parallel to the required plane for the TEM sample.

5. The method of claim 1, where the backside milling is performed with the axis of the ion beam substantially parallel to the required plane for the TEM sample.

6. An apparatus for preparing a TEM sample by backside milling of a sample extracted from a workpiece in an energetic-beam instrument; the apparatus comprising:
a stage capable of motion and tilting;
an ion-beam column;
a nanomanipulator having a rotatable probe tip;
a TEM grid; the TEM grid having a plane; the TEM grid held in a fixed holder; the fixed holder disposed in a fixed orientation with respect to the stage;
the apparatus having a geometry defined by the angular relationships between the ion-beam column, the nanomanipulator, and the stage;
where the geometry further comprises:
a rotation angle for the probe tip sufficient to bring an extracted sample attached to the probe tip into an orientation whereby the stage can be moved to position the TEM grid so that the plane of the TEM grid is substantially parallel to a required plane within the extracted sample for a TEM sample;
a tilt angle of the stage sufficient to place the required plane for an extracted TEM sample substantially parallel to the axis of the ion beam, when the extracted sample is attached to the TEM grid; while the holder is maintained in a fixed orientation with respect to the stage;
so that the extracted sample attached to the TEM grid can be brought into a position allowing backside milling of the extracted sample by the ion beam to prepare a thinned cross-sectional TEM sample.
